(19) United States
(12) Patent Application Publication
(10) Pub. No.: US 2005/0026083 A1
(43) Pub. Date: Feb. 3, 2005

(54) Translucent polyester for enhancing contrast in lithographic printing members

(76) Inventor: Hannoch Ron, Kadima (IL)

Correspondence Address: NATH & ASSOCIATES, PLLC, Sixth Floor, 1030 15th Street, N.W., Washington, DC, 20005, US

(21) Appl. No.: 10/898,619

(22) Filed: Jul. 26, 2004

Related U.S. Application Data
(60) Provisional application No. 60/490,955, filed on Jul. 30, 2003.

(51) Int. Cl. G03F 7/26

(52) U.S. Cl. 430/302

(57) ABSTRACT

The present invention provides for a method of enhancing visible contrast in an imaged lithographic printing plate, which comprises the use of a translucent or opaque polymer as a substrate for said plate. Such polymer may be high molecular weight polyester. The invention further provides a lithographic printing plate which comprises a substrate and at least one imaging layer, the substrate comprising translucent or opaque polymer.

### CROSS-REFERENCE TO RELATED PATENT APPLICATIONS

This patent application claims priority from and is related to U.S. Provisional Patent Application Ser. No. 60/490,955, filed Jul. 30, 2003, this U.S. Provisional Patent Application incorporated by reference in its entirety herein.

### FIELD OF THE INVENTION

The present invention deals with lithographic offset printing members, and more specifically with a method of enhancing contrast in such members.

### BACKGROUND OF THE INVENTION

Lithographic offset printing, especially in large formats, involves sophisticated printing presses, which are operated in many cases by more than one pressman. The preparation of the press involves precious labor and time. This may be the reason for on-going attempts to obtain an illustration as close as possible to the end-result before the image is actually printed by the offset press. Customers nowadays are provided with a “proof” print, done by various printing methods such as inkjet, dye sublimation etc., for the purpose of approval. Once the “proof” has been approved, the actual imaging (plate making) process takes place.

Formation of the image on the printing medium involves mechanical, optical and chemical processes. The resultant printing plate must undergo a quality control process, wherein the printing member is being examined by the prepress operators as well as the printer. In the examination process, actual imaging quality and the position of the image on the printing member are being examined. This examination is rendered impossible if the image on the plate is hard to discern from the background (e.g., a metal plate cylinder).

The image on the plate can be observed if there is a visual contrast between the imaged and the non-imaged areas. In most cases, a visual contrast is obtained by coloring the different layers of the printing member with dissimilar hues.

U.S. Pat. No. 6,045,964 to Ellis, et al. suggests introduction of colorants (chromophors) in the form of pigment or dyes into the plate. This is the most common method used by printing member manufacturers. When white light encounters the colored plates, it is not fully reflected. Specific wavelengths are absorbed by the chromophors, a phenomenon that is perceived by the human eye and brain as color.

Another method of coloring printing members, also suggested in the same patent, involves interference, where the color is formed due to the interaction of visible light with the special structure of the printing member.

An additional method for achieving contrast involves using white polymeric films. Visible light is mostly diffused to all directions when it encounters polymeric films loaded with pigments such as barium sulphate or titanium oxide. The diffused light is perceived by the human eye and brain as white color.

### SUMMARY OF THE INVENTION

In one aspect of the present invention there is provided a method of enhancing visible contrast in an imaged lithographic printing plate, comprising the use of a translucent or opaque polymer as a substrate for said plate.

In one embodiment, the polymer is high molecular weight polyester.

In another aspect of the present invention there is provided a lithographic printing plate comprising a substrate and at least one imaging layer, the substrate comprising translucent or opaque polymer.

In one embodiment, the polymer is high molecular weight polyester.

### DETAILED DESCRIPTION OF PREFERRED EMBODIMENTS

The present invention provides a new method of forming contrast in imaged printing members. The method involves use of a translucent or opaque polymer substrate, such as polyester, as the printing member's substrate. The yellowish color of the translucent or opaque substrate emphasizes almost any hue difference between the substrate and layers coated thereon.

Thus, light diffusion is achieved in a novel way, by using the polymer itself, without the need to add color.

Polyester with relatively low molecular weight, such as the one used to produce textile fibers, is transparent, as can be found in Modern Plastics, World Encyclopedia 2000, Mid-November 1999 issue, Vol. 76 No. 12, A-196-A-200, incorporated herein by reference. The low molecular weight keeps the polyester amorphous at room temperature and it is therefore unsuitable for the purpose of the present invention.

Higher molecular weight polyester is used, for example, in the production of bottles, or films with improved mechanical properties for use e.g. as printing plates. The higher molecular weight polyester tends to crystallize upon cooling, causing the transparent film to become translucent when the film thickness is increased up to the thickness where it becomes opaque. Such films, having the appropriate thickness to be used as printing plates and produced of high molecular weight polyester, may comprise enough crystallites to diffuse a substantial quantity of light, thereby creating a highly translucent or near-opaque film.

Translucent polyester films such as Mylar A (DuPont) and Excell XB60 (Toray Saehan), suitable for performing the present invention, may be less expensive, since they require no extra production stages as do clear high molecular weight polyester suitable for formation of lithographic printing plates.

Extra opaque films for further enhancing the contrast can be obtained by adding crystallization initiators and nucleators during the production of the polyester film. This may also apply to polymers other than polyester, such as polypropylene (See attached references).

References:
1. PET or POLYETHYLENE TEREPHTHALATE,
http://www.geocities.com/bpiconsultaz/PET1.html
2. Introduction to Plastics,
http://www.teachingplastics.org/hands on plastics/intro to plastics/index.html
3. Optical Properties of Plastics,
http://engr.bd.psu.edu/pkoch/plasticdesign/optical.htm
4. PP Cristallization and Haze,
http://www.specialchem4polymers.com/tc/clarifiers/index.aspx?id=principle

1. A method of enhancing visible contrast in an imaged lithographic printing plate, comprising the use of a translucent or opaque polymer as a substrate for said plate.

2. The method of claim 1, wherein said polymer is high molecular weight polyester.

3. Lithographic printing plate comprising a substrate and at least one imaging layer, said substrate comprising translucent or opaque polymer.

4. The lithographic printing plate of claim 3, wherein said polymer is high molecular weight polyester.
